(19) United States
(12) Patent Application Publication
(10) Pub. No.: US 2008/0001181 A1
(43) Pub. Date: Jan. 3, 2008

(54) Complementarily doped metal-semiconductor interfaces to reduce dark current in MSM photodetectors

(76) Inventors: Titash Rakshit, Hillsboro, OR (US); Miriam Reshotko, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/477,722

(22) Filed: Jun. 28, 2006

(51) Int. Cl. H01L 27/148

(52) U.S. Cl. 257/233

(57) ABSTRACT

Metal-Semiconductor-Metal (“MSM”) photodetectors and methods to fabricate thereof are described. The MSM photodetector includes a thin heavily doped (“delta doped”) regions deposited at an interface between metal contacts and a semiconductor layer to reduce a dark current of the MSM photodetector. Band engineering at the metal-semiconductor interfaces using complementarily delta doped semiconductor regions to fix two different interface workfunctions. Delta doping the grounded contact interface with p+ and the reverse biased interface with n+ enhances the Schottky barrier faced by both electrons and holes at the point of injection from source contact into the channel and at the point of collection from the channel into the drain contact.

### FIELD

Embodiments of the invention relate generally to the field of semiconductor manufacturing, and more specifically, to semiconductor photodetectors and methods to fabricate thereof.

### BACKGROUND

Currently, dimensions of integrated circuits continue to be scaled down while signal frequencies continue to increase. Scaling down the dimensions of integrated circuits and higher frequencies may put limitations on use of the electrical interconnects, especially for the longer global interconnects. On-chip optical interconnects have the potential to overcome limitations of the electrical interconnects, especially limitations of the global electrical interconnects. A typical optical interconnect link includes a photodetector. Two of the critical parameters of the photodetector are the dark current and the signal-to-noise ratio (“SNR”). The dark current is generally defined as a current that flows in the photodetector when there is no optical radiation incident on the photodetector but when operating voltages are applied. Generally, the signal-to-noise ratio (“SNR”) may be defined as a ratio of a photocurrent (“signal”) to a dark current (“noise”). Therefore, a low dark current for the same photocurrent increases the SNR of photodetectors.

One of the key components of an on-chip optical interconnect link is a photodetector. In order for optical interconnects to be useful for today's prevailing microelectronic processes, it is important that photodetectors are fabricated using silicon process-based technology and that the method of fabrication may be incorporated in a silicon process flow. A metal-germanium-metal (“MGM”) photodetector grown on a silicon substrate is one such example. Due to the presence of high density of interface energy states, the work function of a metal at a metal-germanium (“M-Ge”) interface is pinned at an energy level within approximately 100 meV of the Ge valence band edge independent of the type of contacting metal. Such pinning of the work function renders a metal germanium interface ohmic. Generally, the ohmic type contact has linear and symmetric current-voltage characteristics. The ohmic MGe interface results in a high value of the dark current. The dark current of the MGM photodetectors having such ohmic contact increases by several orders of magnitude and leads to a poor SNR, which is not desired for the performance of MGM photodetectors.

Currently, one way to reduce the dark current of the MGM photodetector involves passivating the surface of Ge by depositing an insulating silicon oxide on a surface of germanium. Another way to reduce the dark current of the Ge photodetector involves inserting an insulating amorphous Ge (“α-Ge”) layer between the metal (e.g., silver) contacts and a germanium channel layer. FIG. 1 shows a cross sectional view 100 of an MGM photodetector having an insulating amorphous germanium (“α-Ge”) layer 103 between silver contacts 104 and a germanium channel layer 102. As shown in FIG. 1, an epitaxial germanium channel layer 102 is grown on a silicon substrate 101 and an insulating amorphous α-Ge layer 103 is inserted between silver contacts 104 and germanium channel layer 102. Insulating amorphous α-Ge layer 103 forms an insulating tunnel barrier at the interface between germanium channel layer 102 and silver contacts 104.

Inserting an insulating layer between the metal contacts and the germanium channel layer, however, may reduce the photocurrent that flows through the metal-semiconductor interface. Reduction in the photocurrent affects the overall performance of the MGM photodetectors. Additionally, inserting the insulating layer between metal contacts and the germanium channel layer may reduce the electric field available in the germanium channel region thus reducing the photocurrent and possibly the SNR further.

### BRIEF DESCRIPTION OF THE DRAWINGS

Embodiments of the present invention is illustrated by way of example and not limitation in the figures of the accompanying drawings in which like references indicate similar elements.

FIG. 1 shows a cross section of a MSM photodetector having an insulating amorphous alpha-semiconductor layer between silver contacts and a semiconductor channel layer.

FIG. 2 is a cross-section of one embodiment of a MSM photodetector.

FIG. 3 is a flowchart of two methods for fabricating a MSM photodetector.

FIGS. 4-15 are cross-sections of a MSM photodetector illustrating a method for fabricating a MSM photodetector.

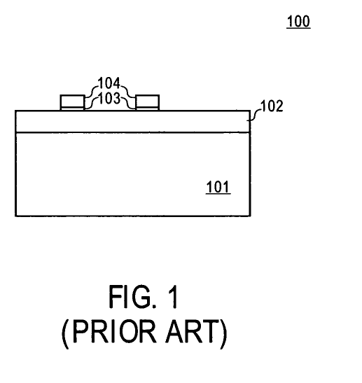

### DETAILED DESCRIPTION

Metal-Semiconductor-Metal (“MSM”) photodetectors and methods to fabricate thereof are described. For one embodiment, the engineering of the work function at the metal-germanium (“MGe”) interface is performed such that the carrier injecting contact interface and the collecting contact interface are complementarily doped. Accordingly, complementarily doping the injecting and collecting interfaces unpins the two interfaces and sets the two interfaces with two different work functions. Furthermore, complementarily doping the two interfaces forms a built-in electric field which increases the Schottky barrier of injection at the injecting interfaces and the Schottky barrier of collection at the collecting interfaces. An MSM photodetector includes a semiconductor layer to provide a photodetector body (“channel”) and metal contacts formed over a top surface of the semiconductor layer at opposite ends of the photodetector channel. Further, the MSM photodetector includes a thin heavily doped (“delta doped”) layer deposited beneath metal contacts on portions of the top surface of the semiconductor layer. Heavy delta doping of the Ge layer in contact with the metallic electrodes leads to a barrier height modulation at the MGe interface, as described in further detail below. The height of the barrier can be controlled by the depth and doping of the delta-doped layer of Ge at the interface. The delta doped regions provide a Schottky barrier type of interface between metal contacts and the portions of the semiconductor layer, as described in further detail below. The delta doped region deposited between metal contacts and the portions of the semiconductor layer reduces a dark current of the MSM photodetector and increases the signal-to-noise ratio (“SNR”) of the MSM photodetector. Computer simulations indicate that the dark current can be reduced for a photodetector with such MGe contacts by at least three orders of magnitude compared to the current state-of-the-art, which in turn significantly improves a signal-to-noise ratio. For one embodiment, the semiconductor channel layer is a layer of an intrinsic semiconductor that has a carrier concentration less than 10¹⁵ cm⁻³. The delta doped region formed to provide the interface between the metal contacts and the intrinsic semiconductor channel layer may be an n-type, or a p-type semiconductor layer. For one embodiment, the delta doped region deposited on portions of the surface of the semiconductor layer beneath metal contacts has a thickness less than 100 nanometers and a dopant concentration (e.g., the concentration of n-type dopants, or p-type dopants) of at least 10¹⁸ cm⁻³. For one embodiment, the delta doped region of germanium (“Ge”) is formed between the metal contacts and portions of the top surface of the intrinsic Ge layer to provide a Schottky barrier interface, as described in further details below. For one embodiment, the MSM photodetector having the delta doped region to provide a Schottky barrier interface is compatible with silicon processing technology, as described in further detail below.

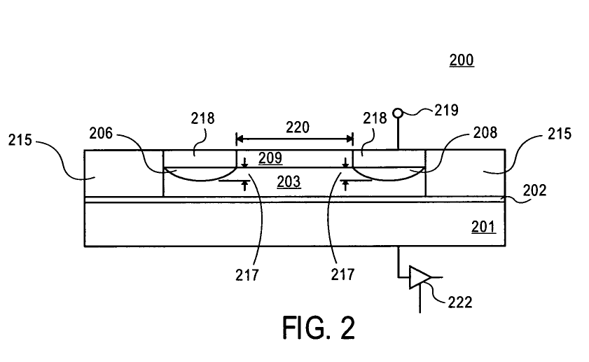

FIG. 2 is a cross-sectional view of one embodiment of an MSM photodetector 200. As shown in FIG. 2, MSM photodetector 200 includes a semiconductor layer 203 deposited on a buffer layer 202 on a substrate 201. For one embodiment, substrate 201 includes monocrystalline silicon. In alternate embodiments, substrate 201 may comprise any material that is used to make any of integrated circuits, passive, and active devices. Substrate 201 may include insulating materials that separate such active and passive devices from a conductive layer or layers that are formed on top of them. Buffer layer 202 may be optionally deposited on substrate 201 to relieve strain that may be induced by the lattice mismatch between substrate 201 and semiconductor layer 203, as shown in FIG. 2. For example, semiconductor layer 203 of Ge may be formed on buffer layer 202 of SiGe on substrate 201 of monocrystalline silicon, as described in further detail below. For various embodiments, semiconductor layer 203 functions as a channel layer in photodetector 200.

As shown in FIG. 2, two metal contacts 218 are formed over two portions of the top surface of semiconductor layer 203. In various embodiments, metal contacts 218 may include copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), platinum Pt, or any combination thereof. For one embodiment, metal contacts 218 include a metal alloy or a compound (e.g., a metal nitride) that includes copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), or platinum (Pt), or any combination thereof. For other embodiments, the metal contacts 218 may comprise another material or materials.

As shown in FIG. 2, metal contacts 218 are separated by an insulating layer 209 deposited on the top surface of semiconductor layer 203. For one embodiment, distance 220 between metal contacts 218 establishes a minimal window on a semiconductor channel of MSM photodetector 200. Insulating layer 209 may include silicon oxide, silicon nitride, or any insulating material suitable in the art. The minimal window on the semiconductor channel of the MSM photodetector 200 may be, e.g., in the approximate range of 100 nanometers (“nm”) to 10 microns (“μm”) depending on the design. For one embodiment, semiconductor layer 203 is a layer of an intrinsic semiconductor. Generally, the intrinsic semiconductor may be defined as a semiconductor, which is only nominally doped. In other words, dopants, e.g., p-type dopants, and/or n-type dopants, are not intentionally added to the intrinsic semiconductor. Typically, the intrinsic semiconductor has the concentration of carriers (e.g., electrons, and/or holes) less than 1×10¹⁵ cm⁻³. In another embodiment, semiconductor layer 203 is a p-type semiconductor. In yet another embodiment, semiconductor layer 203 is an n-type semiconductor.

Thin heavily doped semiconductor layers (“delta doped region”) 206, 208 are formed on portions of the surface of semiconductor layer 203 beneath each of the metal contacts 218, as shown in FIG. 2. Delta doped regions 206, 208 are substantially thin, such that dopants occupy a very small volume. For an embodiment, delta doped regions 206, 208 have a thickness 217, which occupies less than 100 nm at the interface between metal contacts 218 and semiconductor layers 203. Delta doped regions 206, 208 are deposited at the interface between semiconductor layer 203 and metal contacts 218 to reduce the dark current of MSM photodetector 200, as described in further detail below. As shown in FIG. 2, delta doped regions 206, 208 are formed on semiconductor layer 203 beneath metal contacts 218 to provide a different work function for each metal-semiconductor (“MS”) interface.

For one embodiment, the thickness of delta doped regions 206, 208 of Ge is less than 100 nanometers (“nm”) to provide an MGe interface work function such that the MGe interface is a Schottky barrier type contact. In another embodiment, the thickness of delta doped regions 206, 208 is in the approximate range of 5 nm to 20 nanometers. For one embodiment, the thickness of delta doped regions 206, 208 determines the height of the Schottky barrier (not shown), thereby controlling the reduction of the dark current of MSM photodetector 200. In another embodiment, the dopant concentration of delta doped regions 206, 208 determines the height of the Schottky barrier (not shown), whereby controlling the reduction of the dark current of MSM photodetector 200. That is, by controlling the thickness and/or doping concentration of delta doped regions 206, 208 at the metal-semiconductor interface, the reduction of dark current in MSM photodetector 200 is controlled. Forming a delta doped regions 206, 208 on portions of the surface of semiconductor layer 203 immediately beneath metal contacts 218 may reduce the dark current of MSM photodetector 200 by at least 3 orders of magnitude. For example, for a bias voltage of about 1 volt (V) applied to MSM photodetector 200, forming delta doped regions 206, 208 may reduce the dark current by at least three orders of magnitude.

As shown in FIG. 2, delta doped regions 206, 208 define two interfaces between semiconductor layer 203 and metal contacts 218. In an embodiment, delta doped region 206 may be formed at the injecting interface and delta doped region 208 may be formed at the collecting interface. In other embodiments, delta doped region 206 may be formed at the collecting interface and delta doped region 208 may be formed at the injecting interface.

As shown in FIG. 2, insulating layer 215 is disposed on buffer layer 202 on substrate 201 adjacent to opposite sidewalls of semiconductor layer 203. Insulating layer 215 may be any one, or a combination of, silicon dioxide, silicon nitride, polymer, or another insulating material.

MSM photodetector 200 may function by any method such that delta doped regions are oppositely doped to achieve different work functions for the two interfaces and enhance the Schottky barrier at each contact. In an embodiment as shown in FIG. 2, delta doped regions 206 is p+ doped and is disposed at the injecting interface. Conversely, delta doped region 208 is n+ doped and is disposed at the collecting interface. In this embodiment, due to the doping scheme, built-in electric field is present across the photodetector channel, between at the injecting and collecting interfaces. MSM photodetector, according to this embodiment, operates in reverse bias, and the electrons at metal contact disposed above delta doped region 206 faces a high barrier of injection. Likewise, the electrons at the metal contact 218 disposed above delta doped region 208 faces a high barrier of collection. The barriers are similar for holes except that the metal contacts, injection and collection, would be reversed. The voltage is applied to the metal contact 218 disposed above delta doped region 208 at the collecting interface. In an embodiment, 1V is applied to the metal contact 218 disposed above delta doped region 208 at the collecting interface. Alternatively, the metal contact 218 disposed above delta doped region 208 at the injecting interface is grounded. In other embodiments, different voltages may be used.

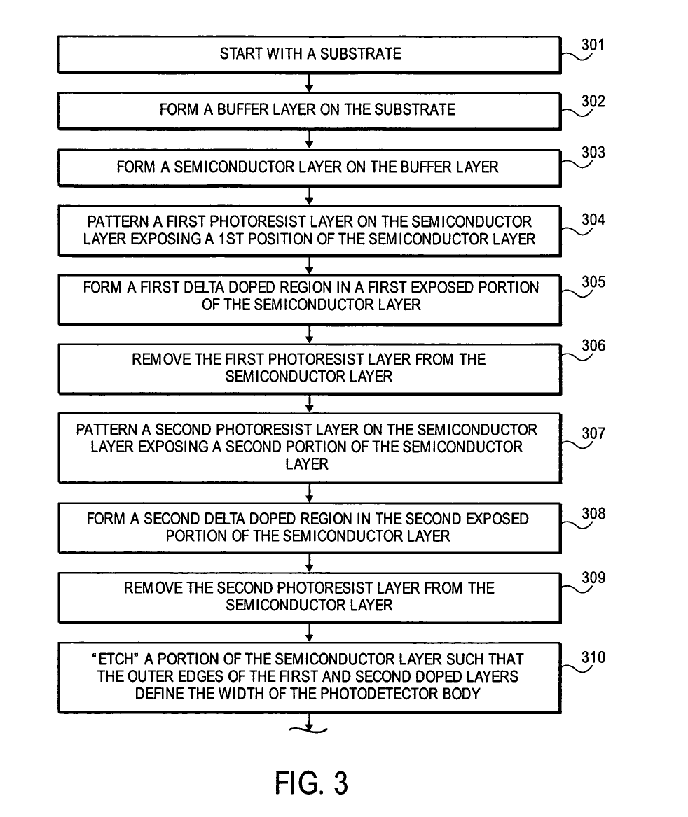

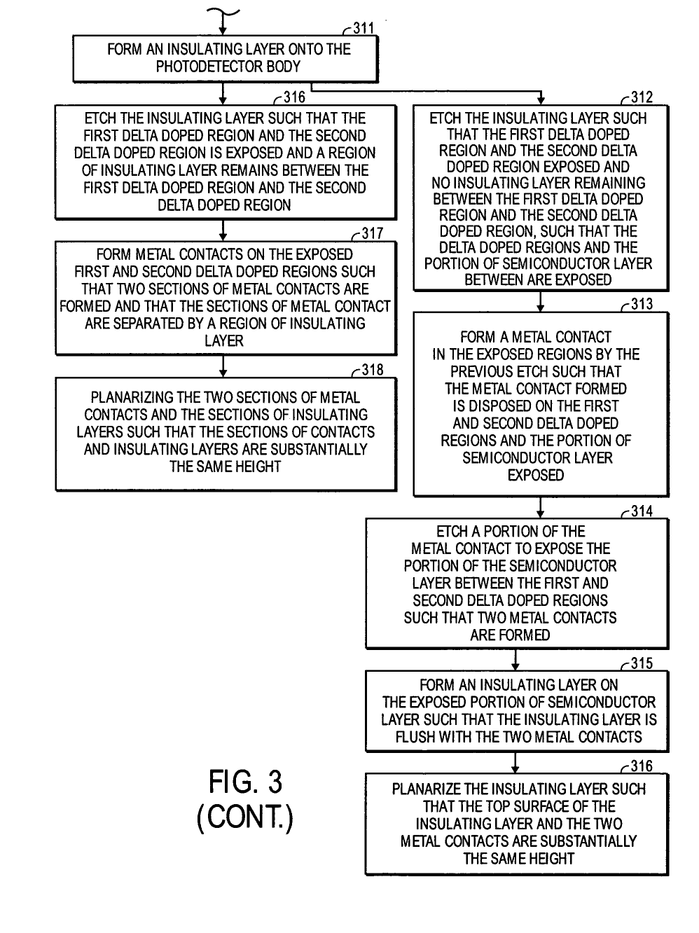

FIG. 3 shows flowchart 300 which illustrates two processes for forming a MSM photodetector. The first process may be defined as operations 301-315 and the second process may be defined as operations 301-311 and 316-318.

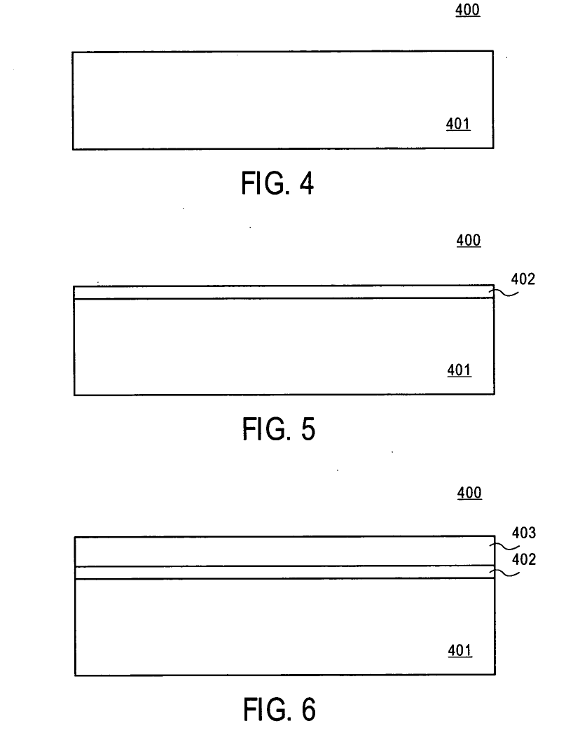

FIG. 4 is a cross-sectional view of the start of a process to fabricate a MSM photodetector according to a process embodiment defined by operations 301-311 and 316-318. As shown in FIG. 4, the process begins with substrate 401 (block 301) on which subsequent layers and devices may be formed. For one embodiment, substrate 401 includes monocrystalline silicon. For one embodiment, substrate 401 is a p-Si substrate. In alternate embodiments, substrate 401 comprises any material used to make integrated circuits, passive, and/or active devices, e.g., gallium arsenide (“GaAs”), indium gallium arsenide (“InGaAs”), silicon carbide (“SiC”), and/or any other semiconductor materials. Substrate 401 may include insulating materials, e.g, silicon oxide, silicon nitride, polymers that separate such active and passive devices from a conductive layer or layers that are formed on top of them.

FIG. 5 shows the stage in the fabrication process of a MSM device after a buffer layer 402 is formed on top of substrate 401 (block 302). Buffer layer 402 may be deposited on substrate 401 to overcome a lattice mismatch between substrate 401 and a semiconductor layer formed over substrate 401 later on in the process. Such a lattice mismatch may lead to many defects, e.g., threading dislocations, stress or strains in the semiconductor layer. Buffer layer 402 is formed to compensate for the lattice mismatch and relieve strain between substrate 401 and a semiconductor channel layer formed later on in the process. Buffer layer 402 may be formed on substrate 401 using any suitable method known in the art such as molecular beam epitaxy (“MBE”), chemical vapor deposition (“CVD”), or sputtering. For one embodiment, buffer layer 402 of SiₓGe₁₋ₓ is epitaxially grown on substrate 401 of monocrystalline silicon to compensate for about 4% lattice mismatch between Si substrate and a Ge layer formed later on in the process. For one embodiment, the relative content X of Si in buffer layer 402 of SiₓGe₁₋ₓ gradually decreases from 1 at the top surface of substrate 401 of Si to 0 at the top surface of the buffer layer 402. For one embodiment, the thickness of buffer layer 402 is in the approximate range of 200 angstroms (“Å”) to 10 μm.

FIG. 6 shows the stage in the fabrication process of a MSM device after a semiconductor layer 403 is formed on buffer layer 402 (block 303). For various embodiments, semiconductor layer 403 provides a channel for an MSM photodetector. For one embodiment, semiconductor layer 403 is an intrinsic semiconductor layer having a concentration of carriers (e.g., electrons, and/or holes) less than 1×10¹⁵ cm⁻³. For one embodiment, a carrier concentration in intrinsic semiconductor layer 403 is in the approximate range of 1×10¹² cm⁻³ to 1×10¹⁵ cm⁻³. In another embodiment, semiconductor layer 403 is an n-type layer having a concentration of electrons between about 5×10¹³ cm⁻³ to about 10¹⁸ cm⁻³. In yet another embodiment, semiconductor layer 403 is a p-type layer having a concentration of holes about 5×10¹³ cm⁻³ to about 10¹⁸ cm⁻³. Other carrier concentrations may be present in other embodiments. Semiconductor layer 403 may be any one, or a combination of, semiconductor materials, e.g., germanium, silicon, GaAs, SiC, GaN, InGaAs, InSb, SiC, or other semiconductor materials. For one embodiment, semiconductor layer 403 is intrinsic Ge, having a carrier concentration less than 1×10¹⁵ cm⁻³, and is deposited on buffer layer 402 of SiₓGe₁₋ₓ. The relative content X of Si in buffer layer 402 of is gradually reduced from 1 at substrate 401 of silicon to zero at semiconductor layer 403 of Ge. In another embodiment, semiconductor layer 403 is formed directly on substrate 401 without buffer layer 402. For example, semiconductor layer 403 of Si may be formed directly on substrate 401 of monocrystalline silicon. Semiconductor layer 403 may be deposited over substrate 401 using any suitable method known in the art such as molecular beam epitaxy (“MBE”), chemical vapor deposition (“CVD”), and sputtering. For one embodiment, the thickness of semiconductor layer 403 is between about 100 nm to about 10 μm. The thickness of semiconductor layer 403 may depend on operating parameters such as wavelength, responsivity, or speed of the MSM photodetector. For example, if the operating wavelength is about 1550 nm, a thinner semiconductor layer 403 of Ge may be formed to increase the channel mobility, and a thicker semiconductor layer 403 of Ge may be formed to provide higher responsivity. For example, if the operating wavelength is about 850 nm that may be absorbed by both Ge and Si materials, a thicker semiconductor layer 403 of Ge may be formed to provide a greater channel mobility because the carriers are not absorbed as much by the substrate if the channel is thicker. For one embodiment, the thickness of semiconductor layer 403 of Ge is in the approximate range of 0.1 μm to 1.5 μm to absorb the infrared light having wavelengths between about 850 nm to about 1550 nm.

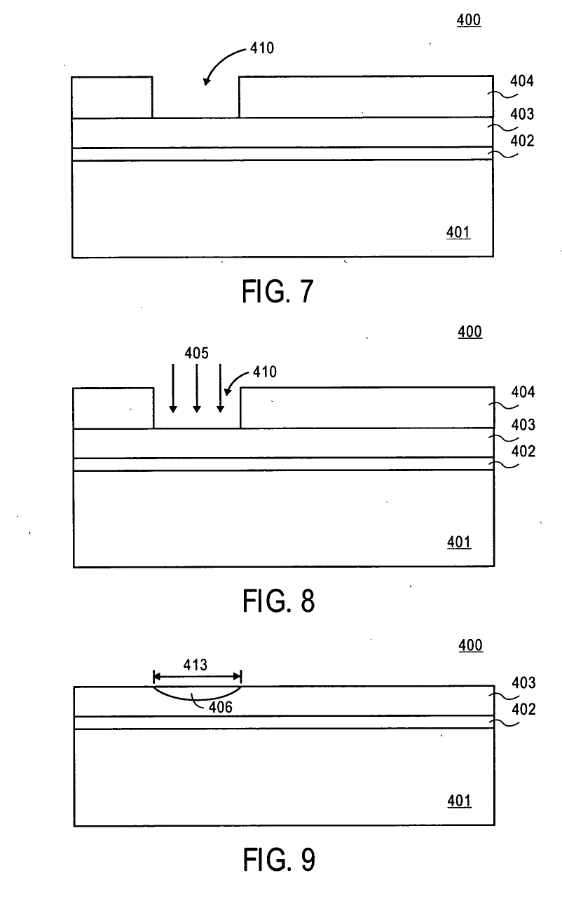

FIG. 7 shows the stage in the fabrication process of a MSM device after a photoresist layer 404 is patterned on semiconductor layer 403 in anticipation of forming a doped region (block 304). As shown in FIG. 7, photoresist layer 404 is patterned to form opening 410 to expose a region of semiconductor layer 403. Patterning may include a combination of depositing, exposing, and developing photoresist layer 404 on semiconductor layer 403 or any other suitable method known in the art. For one embodiment, the size of opening 410 in photoresist layer 404 is determined by the size of contacts formed later on in the process.

FIG. 8 shows the stage in the fabrication process of a MSM device when the region of exposed semiconductor layer 403 in opening 410 is doped (block 305). Doping can be achieved using one of techniques known to one of ordinary skill in the art of semiconductor manufacturing, e.g. using ion implantation, blanket deposition (e.g., epitaxy), diffusion, and spin coating. For one embodiment, the energy of dopant ions during ion implantation is maintained such, that the thickness of the doped region does not exceed 100 nm. For one embodiment, the dose of dopant ions during ion implantation is maintained to provide a dopant concentration of at least 5×10¹⁸ cm⁻³ in doped region. For one embodiment, after ion implantation, semiconductor structure 400 is annealed to activate the dopants. For one embodiment, annealing temperature to activate dopants in the doped region is in the approximate range of 200° C. to 700° C.

FIG. 9 shows the stage in the fabrication process of a MSM device after photoresist layer 404 has been removed from the surface of semiconductor layer 403 such that delta doped region 406 is fully exposed (block 306). Photoresist layer 404 may be removed by any suitable method known in the art. In an embodiment, photoresist layer 404 is removed by an ash or wet etch process.

For one embodiment, the concentration of dopants (e.g., n-type, or p-type dopants) in delta-doped layer 406 is higher than the concentration of dopants in semiconductor layer 403 by at least two orders of magnitude. For one embodiment, a dopant concentration in delta-doped region 406 is at least 1×10¹⁸ cm⁻³, and a carrier concentration in semiconductor layer 403 is less than 1×10¹⁶ cm⁻³. For one embodiment, the thickness of delta-doped region 406 is smaller than the thickness of semiconductor layer 403 by at least a factor of 5. For example, the thickness of delta-doped region 406 may be less than 100 nm, and the thickness of semiconductor layer 403 may be up to 500 nm. In another embodiment, the thickness of delta-doped layer 406 may be less than 100 nm. For one embodiment, delta-doped layer 406 is a n-type semiconductor layer having an n-type dopant concentration of at least 1×10¹⁸ cm⁻³ and delta-doped region 408 is p-type having a p-type dopant concentration of at least 1×10¹⁸ cm⁻³. In another embodiment, delta-doped region 406 is a p-type semiconductor layer having a p-type dopant concentration of at least 1×10¹⁸ cm⁻³. For one embodiment, delta-doped region 406 has a dopant concentration in the approximate range of 1×10¹⁸ cm⁻³ to 1×10²¹ cm⁻³. For one embodiment, delta-doped layer 406 is formed by adding dopants 405 onto portions 410 of semiconductor layer 403, as shown in FIG. 9. For one embodiment, delta-doped layer 406 of Ge having a dopant concentration of at least 1×10¹⁸ cm⁻³ may be formed by adding n-type dopants (e.g., arsenic (As), phosphorus (P), antimony (Sb)) into portions 410 of semiconductor layer 403 of Ge. In another embodiment, delta-doped layer 406 of Ge having a dopant concentration of at least 1×10¹⁸ cm⁻³ may be formed by adding p-type dopants (e.g., boron (B)) into portions 410 of semiconductor layer 403 of Ge.

Delta-doped region 406 may contain a heavily doped thin semiconductor layer. For one embodiment, the thickness of delta doped region 406 is varied to control the height of a Schottky barrier at a metal-semiconductor layer 403 interface formed later on in the process. In another embodiment, a dopant concentration in delta doped region 406 is varied to control the height of a Schottky barrier at a metal-semiconductor layer 403 interface formed later on in the process.

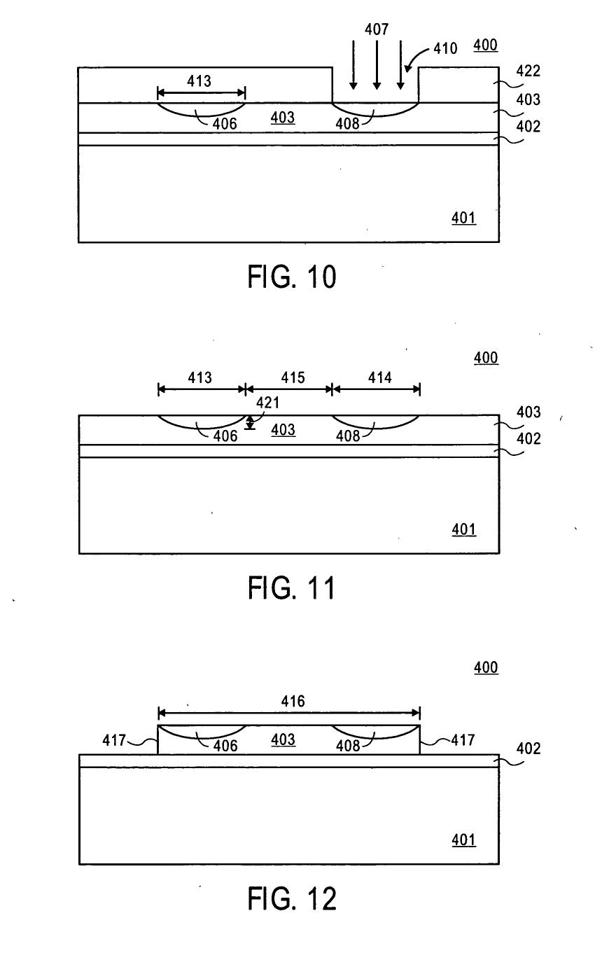

FIG. 10 shows the stage in the fabrication process of a MSM device when a second photoresist layer 422 is patterned on semiconductor layer 403 in anticipation of doping a second region of semiconductor layer 403 (blocks 307, 308). As shown, photoresist layer 422 is patterned to form openings 410 to expose a region of semiconductor layer 403. Patterning photoresist layer 404 may be accomplished by a series of depositing, exposing, and developing a photoresist layer 404 to form openings 410 or by any other suitable method known in the art. Delta doped region 408 may be formed by methods similar to that used to form delta doped region 406 as previously described. For the embodiment illustrated in FIG. 10, delta doped region 408 is doped with a different polarity than that of delta doped region 406. For the embodiment of FIG. 10, p-type dopants 407 are added to the exposed semiconductor region within opening 410 to form a p-type doped region.

FIG. 11 shows the stage in the fabrication process of a MSM device after photoresist layer 422 has been removed from the surface of semiconductor layer 403 fully exposing delta doped regions 406, 408 (block 309). Photoresist layer 422 may be removed by any suitable method known in the art such as the method used to remove photoresist layer 422 as previously described.

Widths 413, 414 and pitch 415 may be defined for delta doped regions 406 and 408 as shown in FIG. 11. The widths 413, 414 of delta-doped regions 406, 408 depend on the size of a contacts to be formed thereupon. In various embodiments, widths 413, 414 may be substantially equal or be substantially wider or narrower in relation to each other. The pitch 415 between portions of delta doped region 406 is defined by parameters of MSM photodetector, e.g., light collecting efficiency, the size, and/or speed. For one embodiment, each dimension (side) of MSM photodetector may be in the approximate range of 1 μm to 100 μm. The width 413 and pitch 414 define the size of contacts and the distance between contacts (pitch) formed later on in the process. Typically, the pitch is referred to the distance between contacts in the periodic array of contacts (electrodes), for example, interdigitated electrodes. The size of the contacts and the distance between contacts determine the speed and a light collection of an MSM photodetector. The distance between contacts relative to the pitch of the contacts also affects photodetector parasitics such as capacitance and resistance. For example, smaller size of contacts may increase the light collection by the photodetector, and smaller pitch may increase the speed of the photodetector. In various embodiments, widths 413, 414 may range from approximately 50 nm to 10 μm, and pitch 415 may range from approximately 50 nm to 100 μm. In an embodiment, widths 413, 414 and pitch 415 of delta doped regions 406, 408 are 0.5, 0.5, and 1 micron respectively.

FIG. 12 shows the stage in the fabrication process of a MSM device after forming a photodetector body 417 by etching portions of semiconductor layer 403 (block 310). As shown in FIG. 12, photodetector body 417 has delta doped regions 406, 408 on portions 410 of the top surface of semiconductor layer 403. For one embodiment, photodetector body 417 is formed by patterning and etching semiconductor layer 403 to width 416. Patterning semiconductor layer 403 to form photodetector body 417 may be accomplished by any suitable method known in the art. The width 416 of photodetector body 417 may range from approximately 500 nm to 100 μm. In other embodiments the width 416 of photodetector body 417 may have different sizes.

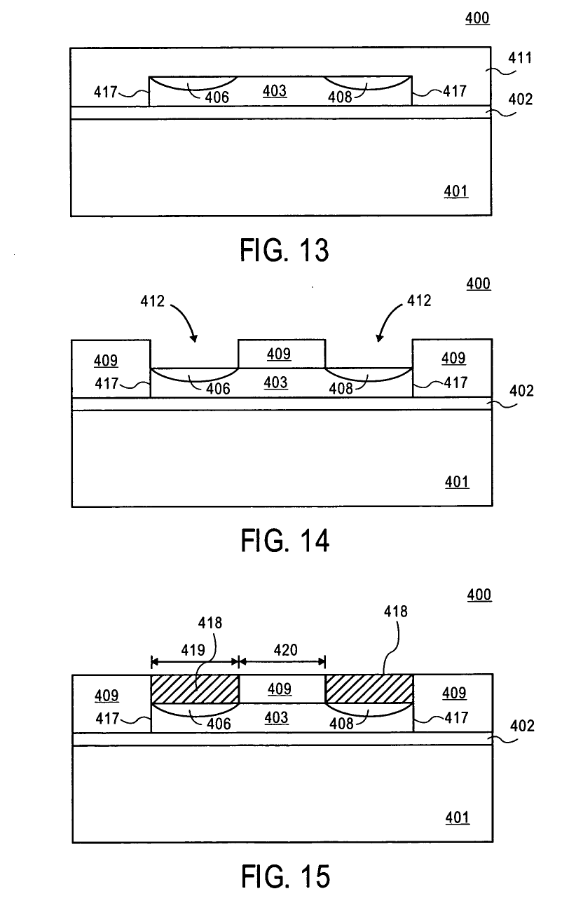

FIG. 13 shows the stage in the fabrication process of a MSM device after insulating layer 411 is formed to overcoat photodetector body 417 and portions of buffer layer 402 (block 311). In various embodiments, insulating layer 407 that includes oxide, e.g., silicon dioxide, is deposited onto photodetector body 417 that includes Ge. Insulating layer 411 may be deposited onto photodetector body 417 using any blanket deposition techniques suitable in the art of semiconductor manufacturing including, but not limited to, spin-on, CVD, or sputtering technique. In alternative embodiments, insulating layer 411 may be any one, or a combination of, silicon dioxide, silicon nitride, polymer, or other insulating materials. For one embodiment, the thickness of insulating layer 411 of silicon dioxide deposited on photodetector body 417 that includes Ge ranges from approximately 50 nm to 100 μm. For one embodiment, after depositing, insulating layer 411 is planarized, e.g., using a chemical-mechanical polishing (“CMP”) technique, to form a substantially flat top surface. The CMP technique is known to one of ordinary skill in the art of semiconductor manufacturing.

FIG. 14 shows the stage in the fabrication process of a MSM device after trenches 412 are formed in insulating layer 411 to expose delta doped regions 406, 408 on portions of semiconductor layer 403 (block 316). For one embodiment, trenches 412 are formed using a patterning and etching technique. The width of trenches 412 determines the size of contacts formed later on in the process. The distance between trenches 412 determines the pitch between contacts formed later on in the process. As shown in FIG. 14, portions of insulating region 409 are formed on buffer layer 402 adjacent to opposite sidewalls of photodetector body 417 that may be used to insulate the photodetector from other devices built on semiconductor substrate 401. As shown in FIG. 14, portion of insulating region 409 is formed on a top surface of photodetector body 417 between portions of delta doped regions 406, 408 that may be used to insulate from each other contacts formed later on in the process. For one embodiment, the portions of insulating region 409 on the top surface of photodetector body 417 between portions of delta doped regions 406, 408 and on buffer layer 402 provide an anti-reflective coating to MSM photodetector 400. For one embodiment, the thickness of the portions of insulating region 409 that provide an anti-reflective coating is determined by operating wavelengths of MSM photodetector 400. For one embodiment, the thickness of these portions of insulating region 409 may be in the approximate range of 10 nm to 10 μm.

FIG. 15 shows the stage in the fabrication process of a MSM device after contacts 418 are formed on delta doped regions 406, 408 (block 317) As shown in FIG. 15, contacts 418 are formed immediately upon delta doped regions 406, 408 to provide a Schottky barrier interface between contacts 418 and semiconductor layer 403. As shown in FIG. 15, contacts 418 are formed by filling trenches 412 with a conductive material, e.g., a metal. For one embodiment, contacts 418 are formed using a damascene technique that includes depositing a metal layer (not shown) into trenches 418 over insulating region 409 using e.g., electroplating. For one embodiment, a barrier layer (not shown) is deposited into trenches 412 before electroplating a metal. In alternate embodiments, contacts 418 may be patterned on delta-doped regions 406, 408 by an subtractive etch technique as defined in the second process recited in flowchart 300. For one embodiment, contacts 418 may include include copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), platinum Pt, or any combination thereof. For one embodiment, contacts 418 include a metal alloy or a compound (e.g., a metal nitride) that includes copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), or platinum (Pt), or any combination thereof. In other embodiments, the metal contacts 418 may comprise another material or materials. For one embodiment, titanium contacts 418 are formed on delta doped regions 406, 408 of Ge on semiconductor layer 403 of intrinsic Ge.

For one embodiment, contacts 418 are formed on photodetector body 417 parallel to each other. In another embodiment, contacts 418 are deposited on photodetector body 417 to form interdigitated, interdigitized contacts. In yet another embodiment, contacts 418 are deposited on photodetector body 417 to form interleaved contacts.

Contacts 418 may be further planarized such that the height of contacts 418 and insulating region 409 are substantially the same.

For an embodiment as set forth in blocks 312, 313, 314, 315, and 316 contacts 418 may be formed by a subtractive etch process. As recited in block 312, insulating layer 411 is etched such that delta doped regions 406, 408 are exposed and portions of insulating layer 411 between delta doped regions 406, 408 are removed. Essentially, the portion of insulating layer 411 that remains are exterior to delta doped regions 406, 408.

Subsequently, as directed by block 313, a conductive material is formed in the opening created by the previous etch such that the conductive material spans from the exterior portions of insulating layer 414 and covers the delta doped regions 406, 408 and the portion of semiconductor layer 403 exposed. The conductive material may be formed by any suitable method in the art such as, but not limited to, chemical vapor deposition, plasma enhanced deposition

Next, according to block 314, the conductive material is etched to form two sections of the conductive material and expose the portion of semiconductor layer 403 between the delta doped regions. The conductive material may be etched by any suitable method known in the art such that two sections of conductive material are formed and that the portion of semiconductor layer 403 between the delta doped regions are exposed.

Then, as recited in block 315, an insulating material is formed in the opening created by the previous etch such that the insulating material formed is flush with two sections of the conductive material. The insulating material may be formed by any suitable method in the art such as, but not limited to, chemical vapor deposition, oxidation, etc.

Next, as recited in block 316, the insulating material is planarized such that the insulating material and conductive material sections have substantially the same height.

In the foregoing specification, the invention has been described with reference to specific exemplary embodiments thereof. It will be evident that various modifications may be made thereto without departing from the broader spirit and scope of the invention. The specification and drawings are, accordingly, to be regarded in an illustrative sense rather than a restrictive sense.

What is claimed is:

1. A photodetector, comprising:
a substrate;
a semiconductor layer disposed over said substrate, wherein said semiconductor layer comprises a top side and a bottom side;
a n+ doped region and a p+ doped region disposed in portions of a top side of said semiconductor layer;
a first metal contact disposed on said n+ doped region and a second metal contact disposed on said p+ doped region; and
an insulating region disposed above said substrate and adjacent to said semiconductor layer.

2. The photodetector of claim 1, wherein an interface between said n+ doped region and said first metal contact defines a collecting interface and an interface between said p+ doped region and said second metal contact defines an injecting interface.

3. The photodetector of claim 1, wherein said semiconductor layer is an intrinsic semiconductor layer.

4. The photodetector of claim 1, wherein said semiconductor layer comprises germanium.

5. The photodetector of claim 1, wherein said n+ doped region and said p+ doped region each has a dopant concentration of at least 1×10¹⁸ cm⁻³.

6. A device, comprising:
a first delta doped region and a second delta doped region disposed in portions of a semiconductor layer; and
a first metal contact disposed on said first delta doped region and a second metal contact disposed on said second delta doped region, and wherein an insulating layer is disposed between said first metal contact and said second metal contact and wherein an interface between said first metal contact and said first delta doped region is an injecting interface and an interface between said second metal contact and said second delta doped region is a collecting interface.

7. The device of claim 1 further comprising a substrate, wherein an insulating region and said semiconductor layer are disposed upon and wherein said insulating layer is adjacent to said semiconductor layer.

8. The device of claim 7, further comprising a buffer layer disposed between said substrate and said semiconductor layer.

9. The device of claim 6, wherein said first delta doped region is a p+ doped region and said second delta doped region is a second n+ doped region.

10. The device of claim 6, wherein said first delta doped region and said second delta doped region have a thickness in the range of 50 to 100 nanometers.

11. The device of claim 6, wherein said first delta doped region and said second delta doped region have a dopant concentration of at least 1×10¹⁸ cm⁻³.

12. A method, comprising:
forming a semiconductor layer on a substrate;
forming a n+ doped region and a p+ doped region on portions of said semiconductor layer; and
forming metal contacts on said n+ doped region and said p+ doped region.

13. The method of claim 12, further comprising:
forming a buffer layer between said substrate and said semiconductor layer and forming an insulating layer on said substrate and adjacent to said semiconductor layer.

14. The method of claim 12, wherein forming said n+ doped region and said p+ doped region comprises
forming a photoresist pattern on said semiconductor layer wherein said photoresist pattern comprises a first exposed portion of said semiconductor layer and a second exposed portion of said semiconductor layer; and
depositing the n+ doped region on said first exposed portion of said semiconductor layer and depositing said p+ doped region on said second exposed portion of said semiconductor layer.

15. The method of claim 12, wherein forming said metal contacts comprises
forming said insulating layer on said semiconductor layer; forming openings in said insulating layer to expose said n+ doped region and said p+ doped region; and depositing said metal contacts into said openings and on said n+ doped region and said p+ doped region.

16. The method of claim 12, wherein said semiconductor layer is an intrinsic semiconductor layer.

17. The method of claim 12, wherein said thicknesses of said n+ doped region and said p+ doped region are less than 100 nanometers.

18. The method of claim 12, wherein forming said doped n+ region and said doped p+ region includes adding dopants to said portions of said semiconductor layer to a dopant concentration of at least 1×10¹⁸ cm⁻³.

19. The method of claim 12, wherein forming said n+ doped region and said p+ doped region includes varying a thickness of said n+ doped region and said p+ doped region to control a height of a Schottky barrier at a metal-semiconductor interface.

20. The method of claim 12, wherein said forming said n+ doped region and said p+ doped region includes varying a dopant concentration in said n+ doped region and said p+ doped region to control a height of a Schottky barrier at a metal-semiconductor interface.
